(19) United States
(12) Patent Application Publication
(10) Pub. No.: US 2018/0152147 A1
(43) Pub. Date: May 31, 2018

(54) AN ULTRA-LOW-POWER AND LOW-NOISE AMPLIFIER

(71) Applicant: WIZEDSP LTD., TEL-AVIV (IL)

(72) Inventors: OZ GABAI, TEL-AVIV (IL); HAIM PRIMO, GANEY TIKVA (IL)

(21) Appl. No.: 15/575,361

(22) PCT Filed: May 19, 2016
(86) PCT No.: PCT/IB2016/052953

§ 371 Date: Nov. 19, 2017

Related U.S. Application Data
(60) Provisional application No. 62/164,451, filed on May 20, 2015.

(51) Int. Cl. H03F 1/02; H03F 3/345

(52) U.S. Cl. CPC H03F 1/0238; H03F 3/345; H03F 3/3455; H03F 2200/294; H03F 2200/171; H03F 2200/391; H03F 2200/78

(57) ABSTRACT

An amplifier comprising a FET transistor, a bias resistor having a first terminal connected to a gate terminal of the FET transistor, a load resistor having a first terminal connected to a D terminal of the FET transistor, a DC-to-DC step-down converter with an input terminal connected to a supply voltage, and an output terminal connected to a second terminal of the load resistor, a two-pin current-to-voltage converter with a first pin connected to an S terminal of the FET transistor and a second pin connected to ground, and a comparator having a first pin connected to a positive supply voltage, a second pin connected to a negative supply voltage, a third (output) pin connected to a second terminal of the bias resistor, a fourth pin connected to a reference voltage, and a fifth pin connected to the first pin of the current-to-voltage converter.

### CROSS-REFERENCE TO RELATED APPLICATIONS

This application claims the benefit of U.S. Provisional Application No. 62/164,451, filed May 20, 2015, the disclosure of which is incorporated herein by reference in its entirety.

### FIELD

The method and apparatus disclosed herein are related to the field of electronics, and, more particularly, but not exclusively to systems and methods for amplifying an electric signal.

### BACKGROUND

Low-noise amplifiers (LNA) are commonly used as the first amplifier, or the first stage of amplification, in many electronic devices such as in receivers of acoustic signals, electro-magnetic radio frequency (RF), telemetry, and as buffers for many sensors. Low-noise amplifiers usually amplify a very weak signal and therefore the need to have a low internal noise. Battery operated devices add the requirement that the low-noise amplifier also consume very low power.

### SUMMARY

According to one exemplary embodiment, there is provided a method, a device, and a computer program for an amplifier including: a FET transistor, a bias resistor having a first terminal connected to a gate terminal of the FET transistor, a load resistor having a first terminal connected to a D terminal of the FET transistor, a DC to DC step down converter, where an input terminal of the DC to DC step down converter is connected to a supply voltage, and an output terminal of the DC to DC step down converter is connected to a second terminal of the load resistor, a two-pin current to voltage converter, where a first pin is connected to an S terminal of the FET transistor and a second pin is connected to ground, and a comparator with a first pin connected to a positive supply voltage, a second connected to a negative supply voltage, a third pin being an output pin is connected to a second terminal of the bias resistor, a fourth pin connected to a reference voltage, and a fifth pin is connected to the first pin of the current to voltage converter.

According to another exemplary embodiment there is provided an amplifier where the FET is at least one of a JFET P-channel, a JFET N-channel, a MOSFET P-channel, and a MOSFET N-channel.

According to still another exemplary embodiment there is provided an amplifier where where the current to voltage converter is at least one of: a resistor, a bipolar junction transistor, a FET transistor, a JFET transistor, a MOSFET transistor, and a diode.

According to yet another exemplary embodiment there is provided an amplifier where the third pin is connected to the second terminal of the bias resistor through a bi-directional low-pass filter, and the fifth pin is connected to the first pin of the current to voltage converter through a low-pass filter.

Further according to another exemplary embodiment there is provided an amplifier where the FET is at least one of: a JFET P-channel, a JFET N-channel, a MOSFET P-channel, and a MOSFET N-channel.

Still further according to another exemplary embodiment there is provided an amplifier where the current to voltage converter is at least one of: a resistor, a bipolar junction transistor, a FET transistor, a JFET transistor, a MOSFET transistor, and a diode.

Yet further according to another exemplary embodiment there is provided an amplifier where additionally including a DC to DC converter configured to generate at least one of the positive supply voltage, and the negative supply.

Even further according to another exemplary embodiment there is provided an amplifier where the FET transistor has a large W parameter and a small L parameter, and/or a large IDSS current and low input capacitance.

Unless otherwise defined, all technical and scientific terms used herein have the same meaning as commonly understood by one of ordinary skill in the relevant art. The materials, methods, and examples provided herein are illustrative only and not intended to be limiting. Except to the extent necessary or inherent in the processes themselves, no particular order to steps or stages of methods and processes described in this disclosure, including the figures, is intended or implied. In many cases the order of process steps may vary without changing the purpose or effect of the methods described.

### BRIEF DESCRIPTION OF THE DRAWINGS

Various embodiments are described herein, by way of example only, with reference to the accompanying drawings. With specific reference now to the drawings in detail, it is stressed that the particulars shown are by way of example and for purposes of illustrative discussion of embodiments only, and are presented in order to provide what is believed to be the most useful and readily understood description of the principles and conceptual aspects of the embodiment. In this regard, no attempt is made to show structural details of the embodiments in more detail than is necessary for a fundamental understanding of the subject matter, the description taken with the drawings making apparent to those skilled in the art how the several forms and structures may be embodied in practice.

In the drawings:

FIG. 1 is a simplified schematic diagram of a signal chain with low-noise amplifiers (LNA);

FIG. 2A is a schematic diagrams of electric circuitry of a MOSFET-based LNA circuit with a buffer;

FIG. 2B is a schematic diagrams of electric circuitry of a JFET-based LNA circuit with a buffer

FIG. 2C is a schematic diagrams of electric circuitry of a low-noise Electrets Condenser Microphone (ECM) buffer;

FIG. 3 is a simplified electrical schematic diagram of a low-noise amplifier (LNA) using a MOSFET transistor;

FIG. 4 is a simplified electrical schematic diagram of a low-noise amplifier (LNA) using a JFET transistor;

FIG. 5 is a simplified electrical schematic of a basic circuit of an LNA using MOSFET with a low-pass filter (LPF) to reject noise from an operational amplifier;

FIG. 6 is a simplified electrical schematic of an LNA using JFET an LPF to reject noise from an operational amplifier;

FIG. 7 is a simplified electrical schematic of an LNA using MOSFET with detailed LPF to reject noise from an operational amplifier;

FIG. 8 is a simplified electrical schematic of an LNA using JFET with detailed LPF to reject noise from operational amplifier;

FIG. 9 is a simplified electrical schematic of an LNA using MOSFET with LPF to reject noise from an operational amplifier and a voltage inverter for the negative voltage supply; and

FIG. 10 is a simplified electrical schematic of an LNA using JFET with LPF filters implementation to reject noise from an operational amplifier and a voltage inverter for the negative voltage supply.

### DETAILED DESCRIPTION

The present embodiments comprise systems and methods for low-noise amplification of electric signals. The principles and operation of the devices and methods according to the several exemplary embodiments presented herein may be better understood with reference to the following drawings and accompanying description.

Before explaining at least one embodiment in detail, it is to be understood that the embodiments are not limited in its application to the details of construction and the arrangement of the components set forth in the following description or illustrated in the drawings. Other embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document may not be to any scale. Different Figs. may use different scales and different scales can be used even within the same drawing, for example different scales for different views of the same object or different scales for the two adjacent objects.

The purpose of embodiments described below is to provide at least one system and/or method for low-noise amplification of electric signals. In all signal chains, for receivers (acoustic, IR, electro-magnetic RF etc.) and sensors the first block of the signal chain is a Low Noise Amplifier (LNA) buffer, this amplifier/buffer unique property is it's inherent low noise and suitable input and output impendence's, the LNA in some cases is used as a buffer with gain of 1, but still with low noise, such as in the case of Electrets condenser Microphone (ECM), which would have usually a JFET as a low noise buffer.

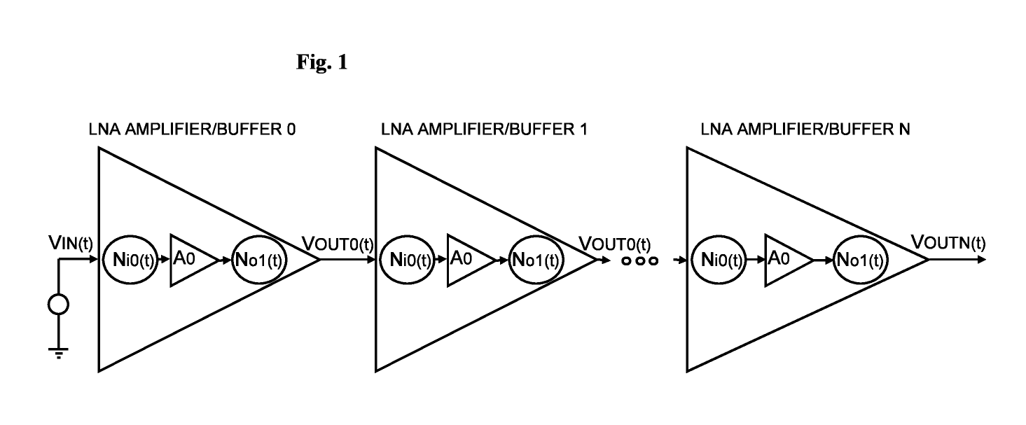

Reference is now made to FIG. 1, which is a simplified schematic diagram of a signal chain with a low-noise amplifier (LNA), according to one exemplary embodiment.

Clearly one can write:

$$Vout ( t ) = Vin ( t ) {\prod }_{q = 0}^{N} {A}_{q} + {\sum }_{q = 0}^{N} {n}_{i n , q} ( t ) {\prod }_{z = q}^{N} {A}_{z} + {\sum }_{q = 0}^{N} {n}_{our , q} ( t ) {\prod }_{z = q + 1}^{N} {A}_{z} \qquad Eq . 1$$

for a given desired

$$C = {\prod }_{z = 0}^{N} {A}_{z}$$

gain one can how that the Signal to noise ratio (SNR)

$$SNR = \frac{{σ}_{Vin}^{2}}{{σ}_{{n}_{i n , 0}}^{2} + \frac{{σ}_{{n}_{i n , 1}}^{2} + {σ}_{{n}_{iout , 0}}^{2}}{{A}_{0}^{2}} + \frac{{σ}_{{n}_{i n , 2}}^{2} + {σ}_{{n}_{iout , 1}}^{2}}{{A}_{0}^{2} {A}_{1}^{2}} + …} \qquad Eq . 2$$

analysis of this expression teach us the importance of the first stage of amplifier chain, to simplify one can think of four stages, in this case we get

$$SNR = \frac{{σ}_{Vin}^{2}}{\begin{matrix}{σ}_{{n}_{i n , 0}}^{2} + \frac{{σ}_{{n}_{i n , 1}}^{2} + {σ}_{{n}_{iout , 0}}^{2}}{{A}_{0}^{2}} + \frac{{σ}_{{n}_{i n , 2}}^{2} + {σ}_{{n}_{iout , 1}}^{2}}{{A}_{0}^{2} {A}_{1}^{2}} + \\ \frac{{σ}_{{n}_{i n , 3}}^{2} + {σ}_{{n}_{iout , 2}}^{2}}{{A}_{0}^{2} {A}_{1}^{2} {A}_{2}^{2}} + \frac{{σ}_{{n}_{iout , 3}}^{2}}{{A}_{0}^{2} {A}_{1}^{2} {A}_{2}^{2} {A}_{3}^{2}}\end{matrix} .} = \frac{{σ}_{Vin}^{2}}{\begin{matrix}{σ}_{{n}_{i n , 0}}^{2} + \frac{{σ}_{{n}_{i n , 1}}^{2} + {σ}_{{n}_{iout , 0}}^{2}}{{A}_{0}^{2}} + \frac{{σ}_{{n}_{i n , 2}}^{2} + {σ}_{{n}_{iout , 1}}^{2}}{{A}_{0}^{2} {A}_{1}^{2}} + \\ \frac{{σ}_{{n}_{i n , 3}}^{2} + {σ}_{{n}_{iout , 2}}^{2}}{{A}_{0}^{2} {A}_{1}^{2} {A}_{2}^{2}} + \frac{{σ}_{{n}_{iout , 3}}^{2}}{{C}^{2}}\end{matrix} .} \qquad Eq . 3$$

If we assume the same noise variances, then from Eq. 4 it is clear that the best choice is to use the first stage with largest gain for example for G₀²=2, G₁²=5, G₂²=10 one can see that the minimal noise combinations is for A₂²=G₀²=2, A₁²=G₁²=5, A₀²=G₂²=10, which gives

$${σ}^{2} + \frac{2 {σ}^{2}}{10} + \frac{2 {σ}^{2}}{50} ++ \frac{{σ}^{2}}{100} .$$

In general, when designing a buffer or amplifier signal chain careful design should be taken to minimize the output noise.

Many LNA or low noise buffer are based on semiconductor active devices like Metal Oxide Semiconductor Field Effect Transistor (MOSFET) or Junction Field Effect Transistor (JFET).

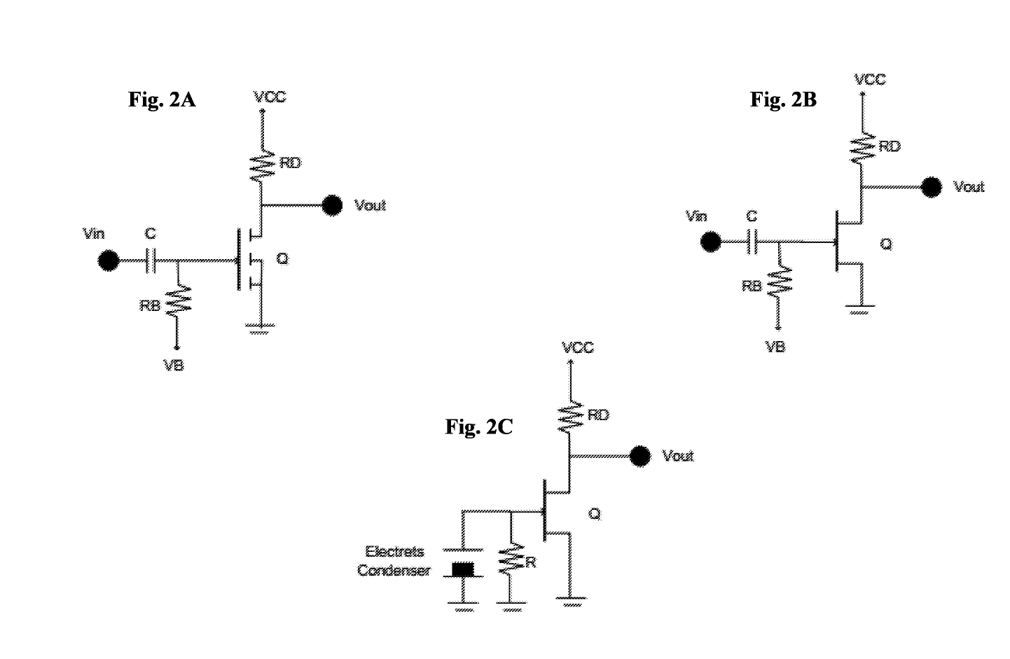

Reference is now made to FIG. 2A, FIG. 2B, and FIG. 2C, which are schematic diagrams of electric circuitry of three versions of LNA and buffer, according to one exemplary embodiment.

As an option, the schematic diagrams of FIGS. 2A, 2B, and 2C may be viewed in the context of the details of the previous Figures. Of course, however, the schematic diagrams of FIGS. 2A, 2B, and 2C may be viewed in the context of any desired environment. Further, the aforementioned definitions may equally apply to the description below.

FIG. 2A shows an example of a MOSFET LNA circuit, FIG. 2B shows an example of a JFET LNA circuit, both are common source configuration. FIG. 2C shows an example of a low-noise Electrets Condenser Microphone (ECM) buffer.

To be used, for example, as buffer or amplifier, the circuits described with reference to FIGS. 2A, 2B, and 2C may work at the saturation regions. To have low noise the circuit may use a bias point with higher Direct Current (DC) drain current

Eq. 4 describes the current in MOSFET, and the drain current in JFET, both in saturation region, while Eq. 5 describes the thermal drain noise density

$$\begin{matrix}{I}_{D} = \frac{{WC}_{ox} μ}{L} {( {V}_{GS} - {V}_{T} )}^{2} = \frac{{WC}_{ox} μ}{{LV}_{T}^{2}} {( 1 - \frac{{V}_{GS}}{{V}_{T}} )}^{2} = {{I}_{DSS} ( 1 - \frac{{V}_{GS}}{{V}_{T}} )}^{2} ⇒ {g}_{m} = - \frac{2}{{V}_{T}} \sqrt{{I}_{D} {I}_{DSS}} & Eq . 4 \\ {I}_{D} == {{I}_{DSS} ( 1 - \frac{{V}_{GS}}{{V}_{P}} )}^{2} ⇒ {g}_{m} = - \frac{2}{{V}_{P}} \sqrt{{I}_{D} {I}_{DSS}} & Eq . 5 \\ {i}_{D , noise , MOSFET}^{2} = 4 KT ( \frac{2}{3} ) {g}_{m} Δ f = 4 KT ( \frac{2}{3} ) \frac{2}{{V}_{T}} \sqrt{{I}_{D} {I}_{DSS}} \\ {i}_{D , noise , JFET}^{2} = 4 KT ( \frac{2}{3} ) {g}_{m} Δ f = 4 KT ( \frac{2}{3} ) \frac{2}{{V}_{P}} \sqrt{{I}_{D} {I}_{DSS}} & Eq . 6\end{matrix}$$

where K is the Boltzmann constant and T is the temperature in Kelvin degrees.

Also

Vₒᵤₜ=gₘR_{D}V_{IN}⇒ [symbol] Vₒᵤₜ² [symbol] =σVₒᵤₜ²=gₘ²R_{D}² [symbol] V_{IN}² [symbol] , Eq. 7

where and are time averages

$$\begin{matrix}〈 {V}_{noise , out}^{2} 〉 = {σ}_{Vnoise}^{2} = {i}_{D , noise , JFET}^{2} {R}_{D}^{2} = 4 KT ( \frac{2}{3} ) {g}_{m} Δ {fR}_{D}^{2} \\ therefore & Eq . 8 \\ SNR = \frac{{g}_{m}^{2} {R}_{D}^{2} 〈 {V}_{IN}^{2} 〉}{4 KT ( \frac{2}{3} ) {g}_{m} Δ {fR}_{D}^{2}} = {g}_{m} \frac{〈 {V}_{IN}^{2} 〉}{4 KT ( \frac{2}{3} ) Δ f} \\ where {g}_{m} = - \frac{2}{{V}_{X}} \sqrt{{I}_{D} {I}_{DSS}} \frac{〈 {V}_{IN}^{2} 〉}{4 KT ( \frac{2}{3} ) Δ f} & Eq . 9\end{matrix}$$

and where V_{X} is either V_{T} or V_{P} for MOSFET or JFET respectively.

As one can see from Eq. 9 the SNR is depended on the square root of the DC drain-current I_{D}, so in order to design low noise LNA or buffer one would have to use high drain-current I_{D}, the power consumption for LNA, buffer is given by Eq. 10

P=I_{D}V_{CC} Eq. 10

The purpose embodiments described below is to provide an ultra-low-power LNA and/or buffer circuitry having SNR similar to LNA/buffer circuitry as shown and described with reference to one or more of FIGS. 2A, 2B, and 2C.

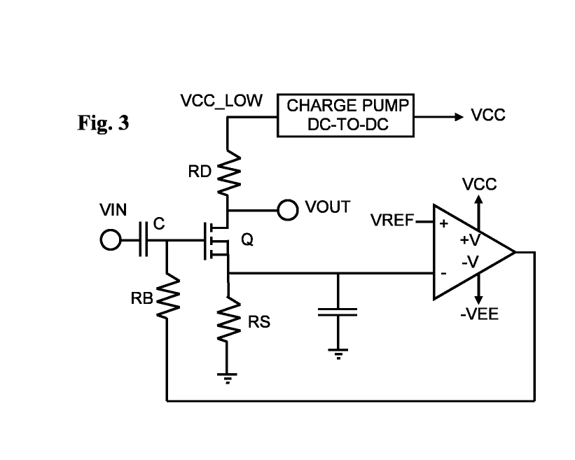

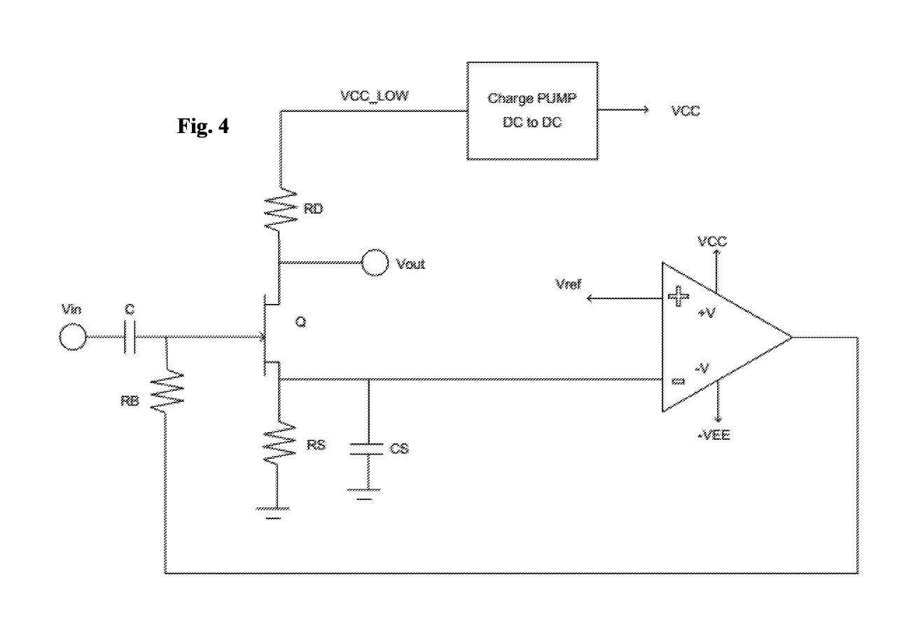

Reference is now made to FIG. 3, which is a simplified electrical schematic diagram of a low-noise amplifier (LNA) using a MOSFET transistor, and to FIG. 4, which is a simplified electrical schematic diagram of a low-noise amplifier (LNA) using a JFET transistor, according to two exemplary embodiments.

As an option, the diagrams of FIGS. 3 and 4 may be viewed in the context of the details of the previous Figures. Of course, however, the diagrams of FIGS. 3 and 4 may be viewed in the context of any desired environment. Further, the aforementioned definitions may equally apply to the description below.

Both LNAs/buffers of FIGS. 3 and 4 may work with extremely low VCC to decrease the power consumption of the amplifier as described by Eq. 10.

The circuits described by FIGS. 3 and 4 may work with minimal supply voltage VCC_LOW (assuming CS not installed) such that the transistors are in saturation where is either V_{T} for MOSFET, or V_{P} for JFET.

$$VCC\_LOW \geq {I}_{DMAX} ( {R}_{D} + {R}_{S} ) + max ( {V}_{gs} - {V}_{x} ) = ( {g}_{M} \vert {V}_{inmax} \vert + {I}_{D} ) ( {R}_{D} + {R}_{S} ) + {V}_{GS} - {V}_{x} + \vert {V}_{inmax} \vert \qquad Eq . 11$$

While V_{GS} is the voltage of junction GS in DC, assuming that the input signal is very low, e.g., a few micro-Volts, and the gain is moderate, then if the supply voltage is a few milli-Volts, then it is possible to compensate for the |V_{in max}| few percentages of the minimum voltage required at DC, and Eq. 11 becomes:

VCC_LOW≥(1+α)(I_{D}(R_{D}+R_{S})+V_{GS}−Vₓ) Eq. 12

where is the compensation above the minimal VCC_LOW required at DC.

For example, assuming a reference LNA/buffer having I_{D}=5 mA, VCC=12V, R_{D}=1 kOhm and V_{P}=−2V, I_{DSS}=5 mA, an LNA/buffer such as shown and described with reference to one or more of FIGS. 2A, 2B, and 2C may have power consumption of 60 milli-Watts and gain of gₘR_{D}=5.

However, assuming that I_{D}=50 uA, decreasing the current by 100, with the same SNR as in Eq. 9, I_{DSS} should be increased by 100, for example by increasing the W parameter and decreasing the L parameter of the transistor.

As

$${g}_{m} = \frac{2}{{V}_{p}} \sqrt{{I}_{D} {I}_{DSS}} = 5 {m ( ohm )}^{- 1}$$

remains the same, then to get gain of 5 with R_{D}=1 kOhm and assuming R_{S}=0.1 kOhm we get

$${V}_{GS} - {V}_{P} = \sqrt{\frac{{I}_{D}}{{I}_{DSS}}} \vert {V}_{P} \vert = 0.2 V$$

Applying the result to Eq. 12 with assumption that α=0.05 we have VCC_LOW>0.21 Volts.

Therefore the power consumption is now 10.5 micro-Watts, so that the circuit reduced the power consumption by 5700 keeping the same SNR.

One exemplary embodiment may use a charge pump DC voltage to DC voltage for the purpose of voltage reduction. Such charge pump may have 97% efficiency and may be implemented using switches and capacitors which could be all implemented in an integrated circuit.

One exemplary embodiment may use a comparator with a sense resistor to check the DC drain current. The comparator, as described in FIGS. 3 and 4, may change the bias voltage to RB such that

$${R}_{S} {I}_{D} = {V}_{ref} ⇒ {I}_{D} = \frac{{V}_{ref}}{{R}_{S}} ,$$

where V_{ref} can be few milli-Volts. The comparator with the sense resistor set the bias voltage such that the required DC current will be set to

$${I}_{D} = \frac{{V}_{ref}}{{R}_{S}} .$$

Therefore, according to Eq. 9, the value of the SNR may be retained by decreasing Id and increasing Idss in the same amount. Idss may be decreased, for example, by using a transistor (e.g., a MOSFET and/or JFET transistor) with increased width (W parameter) and decreased length (L parameter), W and L being the physical dimensions of the transistor.

Although FIGS. 2A, 2B, 2C, 3 and 4 disclose circuitry for an N-channel MOSFET and/or an N-channel JFET, the method may be applied to P-channel JFET and/or P-channel MOSFET.

The comparator/operational amplifier works in the DC range and could be implemented using extremely low-power consumption. In such case the noise from the operational amplifier/comparator may be injected to the LNA/buffer.

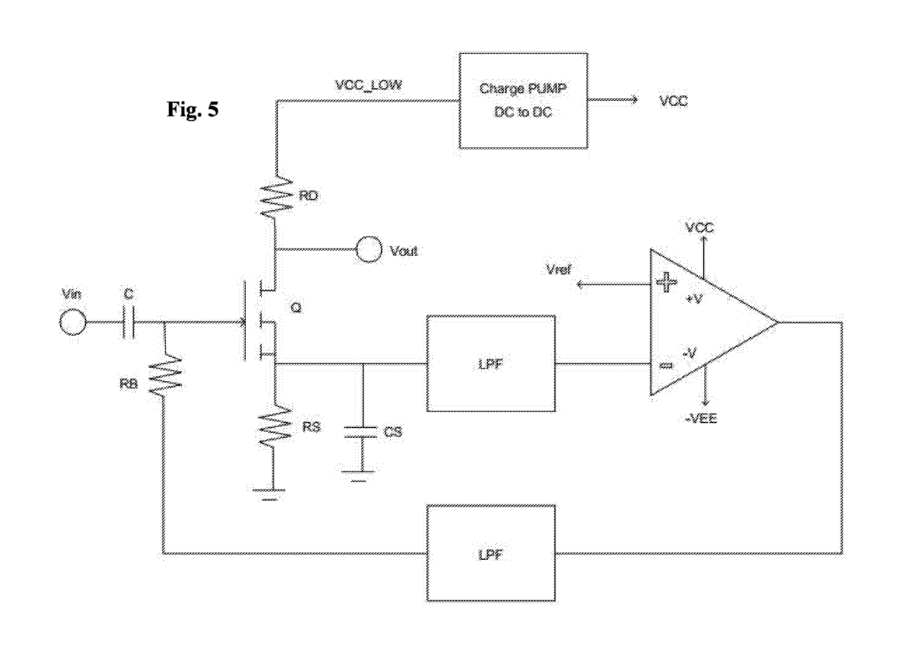

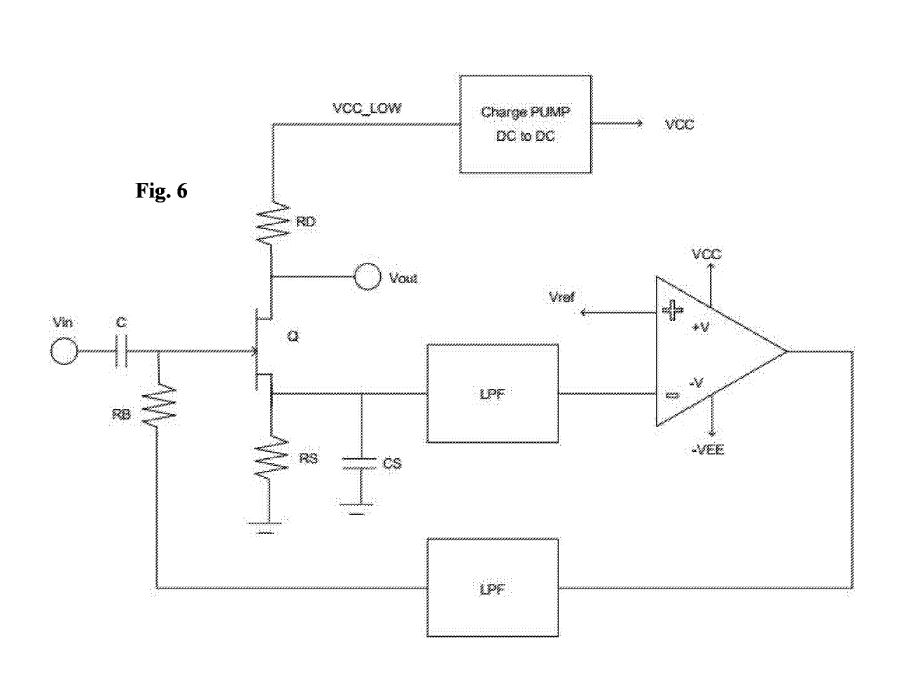

Reference is now made to FIG. 5 and FIG. 6, which are simplified electric schematic diagram of an LNA circuit with a low-pass filter (LPF), according to two exemplary embodiments.

As an option, the electric schematic diagram of FIGS. 5 and 6 may be viewed in the context of the details of the previous Figures. Of course, however, the electric schematic diagram of FIGS. 5 and 6 may be viewed in the context of any desired environment. Further, the aforementioned definitions may equally apply to the description below.

FIGS. 5 and 6 describe improved circuits one or more LPFs to reject noises from the operational amplifier/comparator. FIG. 5 shows a basic circuit of LNA using MOSFET with two LPF filters, while FIG. 6 shows a basic circuit of LNA using JFET with two LPF filters.

The LPF from the sense resistor may work in a bi-directional mode, from the FET transistor to the operational amplifier to pass the sense voltage, and from the operational amplifier to the FET transistor as a filter to reject noise. The LPF from the operational amplifier to RB resistor may work in one direction—from the operational amplifier to the RB resistor.

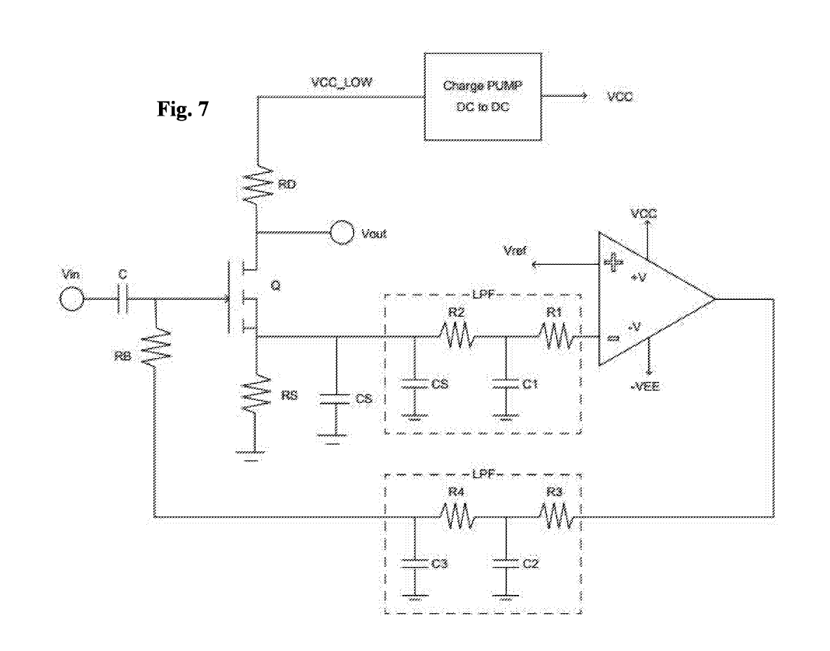

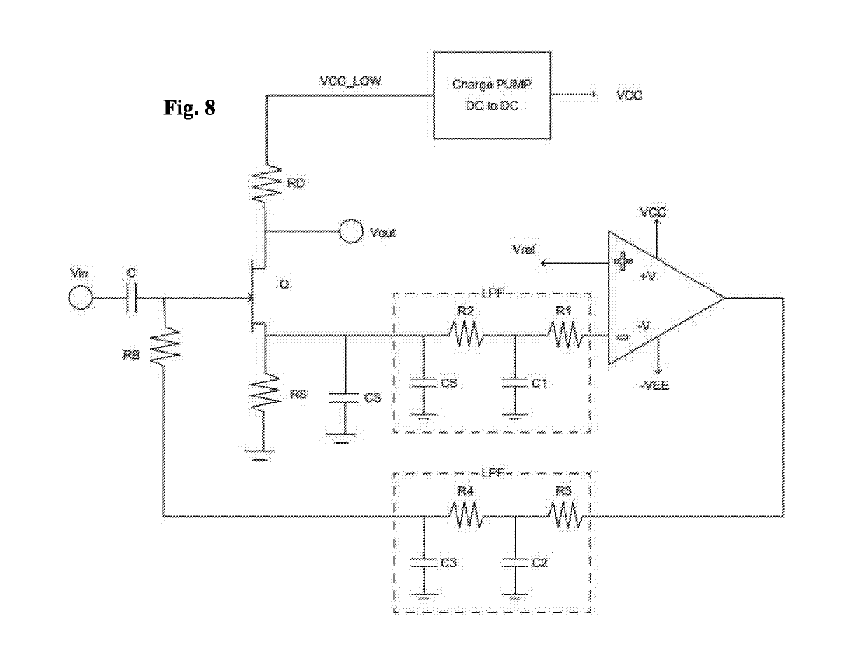

Reference is now made to FIG. 7 and FIG. 8, which are two electric schematic diagrams of an LNA with detailed schematics of the LPFs, according to two exemplary embodiments.

As an option, the schematic diagrams of FIGS. 7 and 8 may be viewed in the context of the details of the previous Figures. Of course, however, the schematic diagrams of FIGS. 7 and 8 may be viewed in the context of any desired environment. Further, the aforementioned definitions may equally apply to the description below.

FIGS. 7 and 8 show a possible implementation to the LPF filters of FIGS. 5 and 6. FIG. 7 describes an LNA circuit using MOSFET while FIG. 8 describes the basic an LNA circuit using JFET.

FIG. 7 shows two LPFs. A first LPF includes resistors R1, R2, and capacitors C1, and CS connecting between the operational amplifier/comparator input to the source. This circuit may block the input thermal noise of the operational amplifier/comparator to the source of the FET amplifier.

A similar LPF including resistors R3, R4, and capacitors C2, C3 is connected between the operational amplifier/comparator and the RB resistor. This LPF may block the operational amplifier/comparator output noise. This design may provide an extremely low current (in the range of nano-Amperes) operational amplifier/comparator.

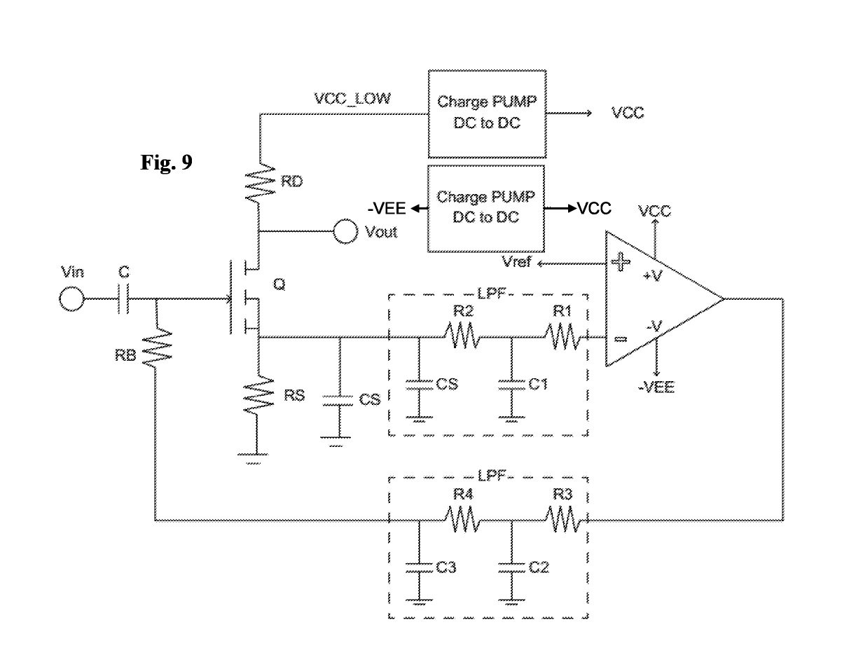

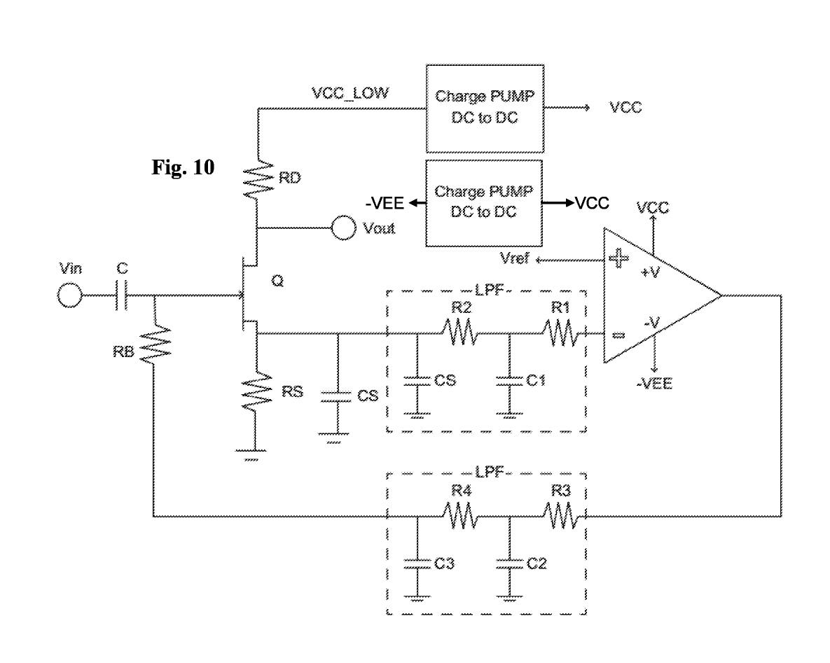

Reference is now made to FIG. 9 and FIG. 10, which are simplified electric schematic diagrams of an LNA circuit with a DC-to-DC voltage inverter supplying negative voltage, according to two exemplary embodiment.

As an option, the schematic diagrams of FIGS. 9 and 10 may be viewed in the context of the details of the previous Figures. Of course, however, the schematic diagrams of FIGS. 9 and 10 may be viewed in the context of any desired environment. Further, the aforementioned definitions may equally apply to the description below.

FIG. 9 describes an LNA circuit using MOSFET with LPF filters implementation to reject noise from operational amplifier and a voltage inverter for the negative voltage supply. FIG. 10 describes an LNA circuit using JFET with LPF filters implementation to reject noise from operational amplifier and a voltage inverter for the negative voltage supply. Although not mentioned, all of the circuit described with N channel JFET or N Channel MOSFET could be implemented using a P channel JFET or P channel MOSFET

It is appreciated that certain features, which are, for clarity, described in the context of separate embodiments, may also be provided in combination in a single embodiment. Conversely, various features, which are, for brevity, described in the context of a single embodiment, may also be provided separately or in any suitable sub-combination.

Although descriptions have been provided above in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art.

1. An amplifier comprising:
a) a FET transistor;
b) a bias resistor having a first terminal connected to a gate terminal of the FET transistor;
c) a load resistor having a first terminal connected to a D terminal of the FET transistor;
d) a DC to DC step down converter, wherein an input terminal of the DC to DC step down converter is connected to a supply voltage, and an output terminal of the DC to DC step down converter is connected to a second terminal of the load resistor;
e) a two-pin current to voltage converter, wherein a first pin is connected to an S terminal of the FET transistor and a second pin is connected to ground; and
f) a comparator with a first pin connected to a positive supply voltage, a second connected to a negative supply voltage, a third pin being an output pin is connected to a second terminal of the bias resistor, a fourth pin connected to a reference voltage, and a fifth pin is connected to the first pin of the current to voltage converter.

2. The amplifier according to claim 1 wherein the FET is at least one of a JFET P-channel, a JFET N-channel, a MOSFET P-channel, and a MOSFET N-channel.

3. The amplifier according to claim 1 wherein the current to voltage converter is at least one of: a resistor, a bipolar junction transistor, a FET transistor, a JFET transistor, a MOSFET transistor, and a diode.

4. The amplifier according to claim 1 wherein the third pin is connected to the second terminal of the bias resistor through a bi-directional low-pass filter, and the fifth pin is connected to the first pin of the current to voltage converter through a low-pass filter.

5. The amplifier according to claim 4 wherein the FET is at least one of: a JFET P-channel, a JFET N-channel, a MOSFET P-channel, and a MOSFET N-channel.

6. The amplifier according to claim 4 wherein the current to voltage converter is at least one of: a resistor, a bipolar junction transistor, a FET transistor, a JFET transistor, a MOSFET transistor, and a diode.

7. The amplifier according to claim 1, additionally comprising a DC to DC converter configured to generate at least one of the positive supply voltage, and the negative supply.

8. The amplifier according to claim 1, wherein the FET transistor has at least one of:
a large W parameter and a small L parameter; and
a large IDSS current and low input capacitance.

9. The amplifier according to claim 4, additionally comprising a DC to DC converter configured to generate at least one of the positive supply voltage, and the negative supply.

10. The amplifier according to claim 4, wherein the FET transistor has at least one of:
a large W parameter and a small L parameter; and
a large IDSS current and low input capacitance.
